(19) United States
(12) Patent Application Publication
(10) Pub. No.: US 2009/0245332 A1
(43) Pub. Date: Oct. 1, 2009

(54) Correlator And Ultrawideband Radio Receiving Apparatus Incorporating The Same

(76) Inventors: Satoru Ishii, Chiba (JP); Yasutaka Koike, Chiba (JP); Ryuji Kohno, Kanagawa (JP)

Correspondence Address: QUARLES & BRADY LLP, 411 E. WISCONSIN AVENUE, SUITE 2040, MILWAUKEE, WI, 53202-4497, US

(21) Appl. No.: 12/400,592

(22) Filed: Mar. 9, 2009

(30) Foreign Application Priority Data
Mar. 27, 2008 (JP) 2008-083249

(51) Int. Cl. H04B 1/707; H03D 1/00

(52) U.S. Cl. 375/150; 375/340; 375/E01.002

(57) ABSTRACT

A correlator (i.e., a despreading filter) and an ultrawideband radio receiving apparatus that incorporates the correlator are provided. In one embodiment, a correlator multiplies a plurality of output signals output by a plurality of delay elements that are series-connected by a predetermined coefficient of either +1 or −1 and then sums the plurality of output signals, the delay element including a delay line and an amplifier; the delay line being configured by serially connecting a plurality of delay-line elements, each of the delay-line elements being a low pass filter that has an inductor and a capacitor; the amplifier being connected to an output of a last-stage delay-line element of the series-connected delay-line elements so as to perform impedance matching with respect to the delay line; an output of the amplifier being connected to a subsequent circuit so as to perform impedance matching with respect to the subsequent circuit, such that a loss of the delay line is compensated for and an output voltage of the delay element is made equal to an input voltage of the delay element.

### CROSS-REFERENCE TO RELATED APPLICATIONS

This application claims the priority benefit of Japanese Patent Application No. 2008-083249 filed on Mar. 27, 2008, the contents of which are hereby incorporated by reference as if fully set forth herein in their entirety.

### STATEMENT CONCERNING FEDERALLY SPONSORED RESEARCH OR DEVELOPMENT

Not applicable.

### TECHNICAL FIELD

The present invention relates to a correlator, which is also called a despreading filter, and an ultrawideband (UWB) radio receiving apparatus incorporating the same.

### BACKGROUND ART

Currently, scarcity of frequency resources available for radio wave communications makes it difficult to use frequencies that are not occupied by existing radio frequency systems. Ultrawideband (UWB) radio transmission technology that transmits data spread over a large bandwidth at very low energy levels offers a solution to effective use of frequency resources. Direct-sequence (DS) spectrum spreading is one of the two basic modulation techniques used in conventional UWB radio signal transmission and reception, the other being multiband orthogonal frequency division multiplexing.

In direct-sequence-based UWB transmission and reception, a digital signal is multiplied by a pseudorandom noise (PN) sequence in order to spread a spectrum and the spectrum-spread signal is transmitted as a radio wave. A DS-UWB receiving apparatus demodulates the received spectrum-spread signal using a correlator. Since the correlator demodulates, i.e., despreads the spectrum-spread signal, it is also called a despreader (for example, refer to Yukiji Yamauchi, Spread Spectrum Communications. 1st ed. Tokyo: Tokyo Denki University Press, Nov. 20, 1994).

The circuit of the correlator is configured as a known-in-the-art digital finite impulse response (FIR) filter constituted by a plurality of shift registers, whose tap coefficients only assume either of +1 or −1. Meanwhile, an analog system whose input signals are analog signals incorporates an analog delay element such as a surface acoustic wave (SAW) filter in place of the shift register (for example, refer to Japanese Patent Application Laid-Open Publication H08-321741).

In general, the digital correlator of the ultrawideband radio transmission systems based upon the spectrum spreading modulation techniques is the digital FIR filter for digital communications while the SAW filter is used as the analog correlator for analog systems. Also, the digital FIR filter is suited for relatively low-speed operation and the SAW filter is widely used in relatively high-speed operation. For instance, the SAW filter is most popular and best suited for processing signals that are modulated by the hitherto predominant spectrum spreading techniques with a maximum bandwidth for a transmit frequency spectrum being in the order of 50 MHz.

### SUMMARY OF INVENTION

In recent years, as the systems built on ultrawideband radio communications technology feature more advanced and sophisticated functionality, it is irrevocable that the bandwidth has to be further expanded. Since a maximum bandwidth for the entire transmit frequency spectrum is 600 MHz under Japan's spectrum regulation requirements stipulated by the Japanese Radio Law, the chip rate in the DS modulation can be up to 500 mega chips per second (Mcps) when the frequency spectrum is spread over the maximum usable bandwidth. However, a correlator using the conventional SAW filter is only capable of achieving a chip rate as high as 50 to 100 Mcps, failing to achieve much higher chip rate.

In view of the above-identified problem existing in the art, the present invention is to provide a relatively inexpensive correlator suitable for an ultrawideband radio transmission with a high chip rate in a range that has hitherto been difficult to exploit. The correlator according to one embodiment of the present invention is a despreading filter) that includes a plurality of delay elements, a plurality of multipliers, and an adder.

The delay elements, each of which has a delay line and an amplifier, are connected in series and each output an output signal.

The delay line of the delay element is configured by a plurality of delay-line elements that are connected in series, the delay-line element being a low pass filter that has an inductor and a capacitor. The amplifier compensates for a loss that occurs in the delay line so that an output voltage of the delay element is equal to an input voltage of the delay element.

The amplifier of the delay element has (a) an input connected to an output of the delay-line element constituting a last stage of the delay line such that impedance matching is obtained between the delay line and the amplifier and (b) an output connected to an input of a subsequent circuit such that the impedance matching is obtained between the amplifier and the subsequent circuit.

The multipliers have a predetermined coefficient of either +1 or −1 and each configured to multiply corresponding each of the output signals supplied from the delay elements by the predetermined coefficient.

The adder sums the output signals that have been multiplied by the predetermined coefficient.

The correlator according to one embodiment of the present invention is constructed by the series-connected delay elements, each of which has the delay line and the amplifier. The delay line of the delay element is constructed by the delay-line elements, i.e., the low pass filters that are connected in series, so that amplitude characteristics and delay characteristics remain constant regardless of the variation of the frequency. Also, the delay line is connected to the output of the delay-line element serving as the last stage of the series-connected delay-line elements for impedance matching with respect to the delay element. Also, the subsequent circuit is connected to the output of the amplifier for impedance matching between the amplifier and the subsequent.

Further, the amplifier of the delay element compensates for a loss that occurs in the delay line and set the output voltage of the delay element equal to the input voltage of the delay element.

Note that, when another delay element is to be connected as a next filter stage, the subsequent circuit that is connected to the output of the amplifier denotes (a) the next-stage delay element and (b) the multiplier circuit having the predetermined coefficient. Also, when another multiplier is only to be connected with no further next-stage delay element, the circuit connected to the subsequent stage only includes the multiplier having the predetermined coefficient. In this manner, the correlator having the predetermined coefficient of either +1 or −1 can be constructed.

In another aspect, the present invention provides an ultrawideband radio receiving apparatus that performs despreading of a received spectrum-spread signal by a correlator which is a despreading filter that includes a plurality of delay elements, a plurality of multipliers, and an adder.

The delay elements, each of which has a delay line and an amplifier, are connected in series and each output an output signal.

The delay line of the delay element is configured by a plurality of delay-line elements that are connected in series, the delay-line element being a low pass filter that has an inductor and a capacitor. The amplifier compensates for a loss that occurs in the delay line so that an output voltage of the delay element is equal to an input voltage of the delay element.

The amplifier of the delay element has (a) an input connected to an output of the delay-line element constituting a last stage of the delay line such that impedance matching is obtained between the delay line and the amplifier and (b) an output connected to an input of a subsequent circuit such that the impedance matching is obtained between the amplifier and the subsequent circuit.

The multipliers have a predetermined coefficient of either +1 or −1 and is each configured to multiply corresponding each of the output signals supplied from the delay elements by the predetermined coefficient.

The adder sums the output signals that have been multiplied by the predetermined coefficient.

The ultrawideband radio receiving apparatus according to one embodiment of the present invention has the correlator that includes a plurality of delay elements. Each of the delay elements has a delay line and an amplifier. The delay line of the delay element is constructed by the delay-line elements, i.e., the low pass filters that are connected in series, so that amplitude characteristics and delay characteristics remain constant regardless of the variation of the frequency. Also, the delay line is connected to the output of the delay-line element serving as the last stage of the series-connected delay-line elements for impedance matching with respect to the delay element. Also, the subsequent circuit is connected to the output of the amplifier for impedance matching between the amplifier and the subsequent circuit.

Further, the amplifier of the delay element compensates for a loss that occurs in the delay line and set the output voltage of the delay element equal to the input voltage of the delay element.

Note that, when another delay element is to be connected as a next filter stage, the subsequent circuit that is connected to the output of the amplifier denotes (a) the next-stage delay element and (b) the multiplier circuit having the predetermined coefficient. Also, when another multiplier is only to be connected with no further next-stage delay element, the circuit connected to the subsequent stage only includes the multiplier having the predetermined coefficient. In this manner, the correlator having the predetermined coefficient of either +1 and −1 can be constructed and the ultrawideband radio receiving apparatus using the correlator is readily applicable to spectrum spreading over a wider frequency spectrum.

With the construction and arrangement described above, the correlator according to one embodiment of the present invention has the inductor, the capacitor, and the amplifier as its main components and achieves high-chip-rate operation with relatively low cost. Also, the ultrawideband radio receiving apparatus using the correlator according to one embodiment of the present invention is readily capable of receiving a spectrum-spread signal over a wider frequency band.

### BRIEF DESCRIPTION OF DRAWINGS

These and other objects, features, and advantages of the present invention will become more apparent upon reading of the following detailed description along with the accompanied drawings, in which:

FIG. 1 schematically explains principles of ultrawideband radio transmission and reception according to one embodiment of the present invention.

FIG. 2 is a block diagram of a despreading filter (i.e., correlator) used in a direct-sequence (DS) modulation according to one embodiment of the present invention.

FIG. 3 shows a delay element for explanation of principles for constructing a delay element of the despreading filter according to one embodiment of the present invention.

FIG. 4 shows transmission characteristics of the delay element shown in FIG. 3.

FIG. 5 shows another delay element for explanation of the principles for constructing the delay element of the despreading filter according to one embodiment of the present invention.

FIG. 6 shows characteristics of the delay element shown in FIG. 5.

FIG. 7 shows the delay element according to one embodiment of the present invention.

FIG. 8 shows characteristics of the delay element shown in FIG. 7.

FIG. 9 shows another delay element according to one embodiment of the present invention.

FIG. 10 shows the delay element shown in FIG. 9 as an equivalent circuit to explain functionality thereof.

FIG. 11 shows polarities of an output with respect to an input for each delay element constituting one filter stage and incorporating a grounded-emitter amplifier circuit according to one embodiment of the present invention.

FIG. 12 shows how tap coefficients of the despreading filter are specified according to one embodiment of the present invention.

FIG. 13 shows a delay element incorporating a coaxial cable in place of a delay line according to another embodiment of the present invention.

### DESCRIPTION OF EMBODIMENT

An ultrawideband radio receiving apparatus according to one embodiment of the present invention is described in detail with reference to the attached drawings.

FIG. 1 explains the principles of ultrawideband (UWB) radio or wireless transmission and reception. The UWB radio transmission technique shown in FIG. 1 is a conceptual rendering of direct-sequence (DS) based modulation.

Referring to FIG. 1, there is a dotted line extending at the center of the figure in a vertical direction defining the left portion and the right portion. Basic operation on a transmitting side, i.e., operation performed by an ultrawideband radio transmitting apparatus (hereafter simply called a transmitting apparatus) is shown in the left portion of FIG. 1. Also, basic operation on a receiving side, i.e., operation performed by an ultrawideband radio receiving apparatus (hereafter simply called a receiving apparatus) corresponds to the right portion of FIG. 1.

A digital signal a(t) that has been modulated in primary modulation based upon for example phase-shift keying (PSK) is multiplied (XORed) by a pseudorandom noise (PN) sequence C(t) and a spectrum-spread transmit signal x(t) is obtained and emitted as a radio wave into the air. The PN sequence takes a form of a rectangular wave with a value of +1 or −1 that is changed according to a predetermined rule. The receiving apparatus multiplies the received transmit signal x(t) by the PN sequence C(t) and thereby obtains a despread signal y(t). The demodulation of the spectrum-spread signal for obtaining the signal y(t) is called despreading and a functional unit that performs the despreading is called a despreading filter, which is also called a correlator. The despread signal y(t) is passed through a band pass filter (BPF). A detector (not shown) performs threshold judgment for the despread signal that has been passed through the BPF to obtain a reproduced digital signal that assumes a value of a zero (0) or one (1).

If the transmitting apparatus and the receiving apparatus in DS-based UWB communications share the same PN sequence C(t), then

C(t)*C(t)=1

where * stands for convolution, and the reproduced digital signal will be identical with the original digital signal a(t) on the side of the transmitting apparatus. Thus, the receiving apparatus can despread the transmit signal x(t) sent by the transmitting apparatus can be despread by the receiving apparatus to obtain the digital signal a(t).

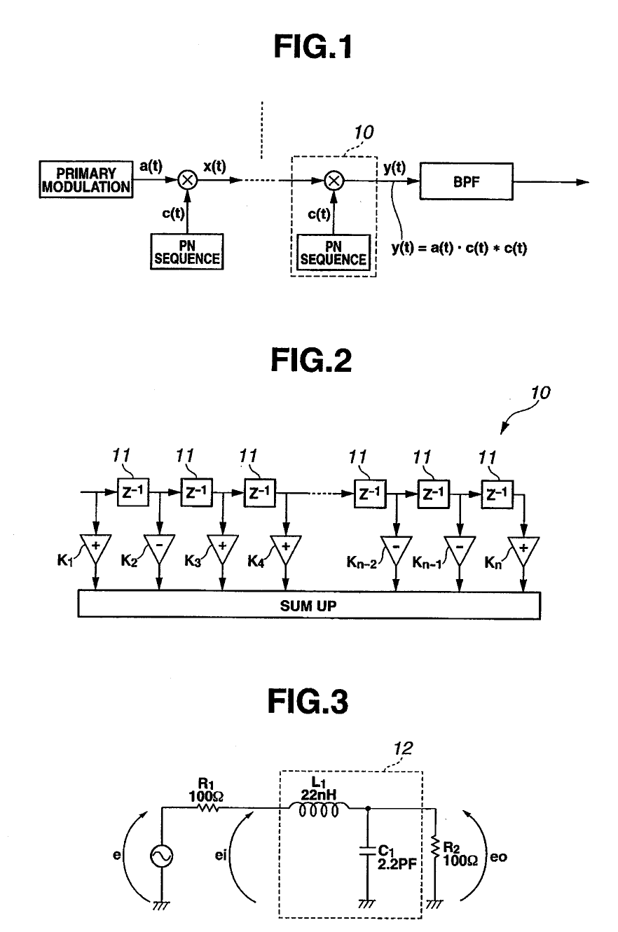

FIG. 2 is a block diagram of a despreading filter used in the DS-based UWB transmission and reception. The despreading filter 10 has a delay element 11, multipliers that have tap coefficients K1 (the first tap coefficient) to Kn (n-th tap coefficient), and an adder (SUM-UP). A rectangle indicated by a symbol “Z⁻¹” represents the delay element 11, and the tap coefficients K1 to Kn i.e., “+” or “−” in triangles correspond to +1 and −1 of the PN sequence of the transmitting side. The positive signs “+” in the triangles indicate the tap coefficient +1 and the negative signs “−” indicate the tap coefficient −1. Since the despreading filter 10 in a sense is an optimum filter for detecting a target signal degraded by noise, the optimum filter with such functionality is called a “matched filter” in the field of communications theory. Further, the matched filter for an UWB radio transmission/reception system detects correlation between the transmit signal x(t) and the PN sequence C(t) and this is why the matched filter is also called a correlator. Since the despreading filter 10 in FIG. 2 has the delay elements that are less by one in number than the tap coefficients, the last delay element is the (n−1)th delay element.

In a practical sense, the delay element 11 indicated by Z⁻¹ is a critical factor in successfully configuring the despreading filter 10 of this type. When the spectrum spreading is performed over a relatively narrow frequency band, the despreading is in most cases achieved by digital signal processing. However, when digital processing has to be made at a high speed of 500 Mcps, the clock speed has to be equal to or higher than 1 GHz in view of the Nyquist theorem, and accordingly difficulty in sampling is caused, making it difficult to obtain an electronic component with such high-speed operation capability. Also, a surface acoustic wave (SAW) technique such as a SAW filter is used in some devices. However, as has been discussed above, it is difficult to realize high-speed operation at a chip rate of 500 Mcps. In addition, the SAW techniques as such are not so flexibly applicable considering various electronic circuit design requirements.

FIG. 3 is intended for explanation of principles of one embodiment of the present invention and illustrates a delay element 12 that can operate at a high speed with a chip rate in the order of 500 Mcps. The delay element 12 has an inductor L1 and a capacitor C1, which are connected so as to constitute a low pass filter. Resistors R1 and R2 are a terminating resistor.

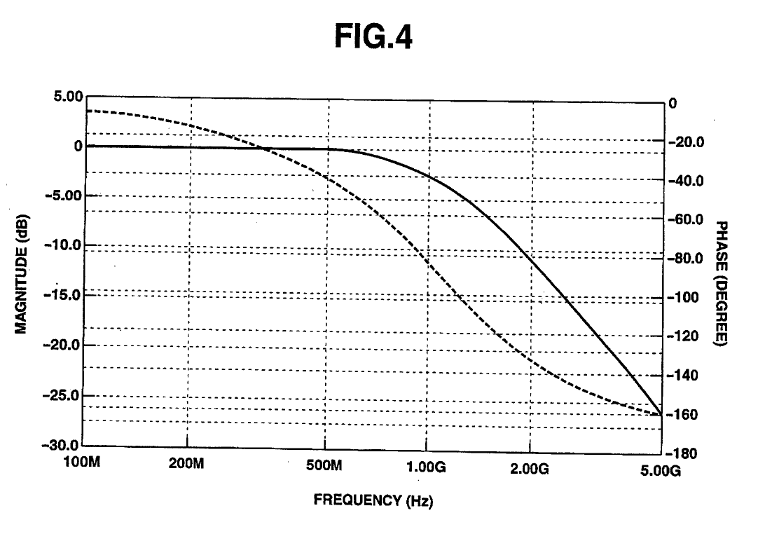

FIG. 4 is a Bode diagram that shows transmission characteristics (eo/ei) of magnitude (amplitude) and phase with respect to frequency of the delay element 12. An input voltage and an output voltage of the delay element 12 are represented by ei and eo, respectively. A solid line in the diagram represents the magnitude |eo/ei| and a dotted line represents the phase (∠eo/ei).

As shown in FIG. 4, the amplitude characteristics of the delay element 12 exhibits substantially no variation both at a frequency of 100 MHz and at a frequency 500 MHz. Meanwhile, a delay of the phase at 500 MHz frequency is about 40°. The amount of delay is 40/360×2 nanoseconds (nsec), which is approximately 0.22 nsec.

In FIG. 3, an input of the delay line 13 is terminated with the 100-Ω resistor R1 and an output is likewise terminated with the 100-Ω resistor R2, which is equal to characteristic impedance Z_{O} that is determined by the inductor L1 and the capacitor C1. In other words, the characteristic impedance Z_{O} can be expressed by the equation (1) and the characteristic impedance Z_{O} in this case will be 100-Ω.

Zₒ=\sqrt{L/C}=\sqrt{(22×10⁻⁹)/(2×10⁻²)}≅100(Ω) (1)

where:
L: inductance of the inductor L1
C: capacitance of the capacitor C1

Since the characteristic impedance Z_{O} is expressed by the equation (1), the same characteristic impedance Z_{O} applies to a given combinations of L and C with the L/C ratio remaining the same.

Referring again to FIG. 2, in order to operate at a chip rate of about 500 Mcps, each delay time of the delay element 11 indicated by a symbol Z⁻¹ of the despreading filter 10 has to be, for example, in the order of 2 nsec. Since the delay element 12 in FIG. 3 that is only constituted by one inductor L1 and one capacitor C1 is capable of obtaining a delay time in the order of 0.22 nsec, the delay element 12 cannot obtain the 2-nsec delay time under a condition of maintaining a predetermined amplitude characteristics.

The following describes how to construct a delay element that is suitable for operation at the 500-Mcps chip rate with the amplitude characteristics remaining substantially constant even at the chip rate of up to 500 MHz.

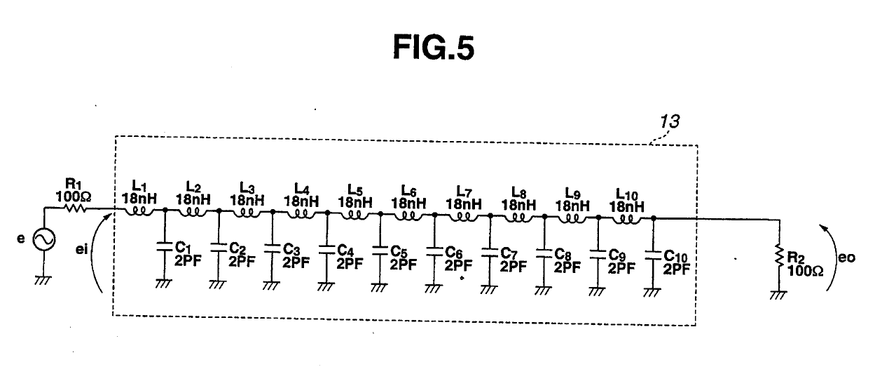

A classical approach to filter design is to construct a filter unit by connecting in series a plurality of filters that share the same characteristic impedance. FIG. 5 shows another delay element 13 for explanation of the principles of the delay element construction according to the preferred embodiment.

The delay element 13 is built based on the above filter design philosophy. The delay element 13 is constructed by connecting in series a plurality of delay-line elements. These delay-line elements are the delay element 12 shown in FIG. 3. This means that the delay-line element that includes an inductor L1 and a capacitor C1 has the same characteristic impedance as those of the other delay-line elements (for example, the delay-line element that includes an inductor L2 and a capacitor C2).

These delay-line elements (delay line 12 shown in FIG. 3) sharing the same characteristic impedance are connected in series to constitute the delay element 13 shown in FIG. 5. In short, the delay element 13 is constructed by the delay-line elements, i.e., the low pass filters having the same characteristic impedance.

The amount of delay De per one delay element 12 is expressed by the equation (2).

De=\sqrt{L×C} (2)

The total amount of delay Da for the entire delay element 13 can be expressed by the equation (3), which is obtained by multiplying the amount of delay given as the equation (2) by the number of stages n of the series-connected delay elements 12. In this case, the total amount of delay Da will be approximately 1.9 nanoseconds (nsec).

Da=n×\sqrt{L×C}=10×\sqrt{(18×10⁻⁵)×(2×10⁻⁹)}≅1.9(nsec) (3)

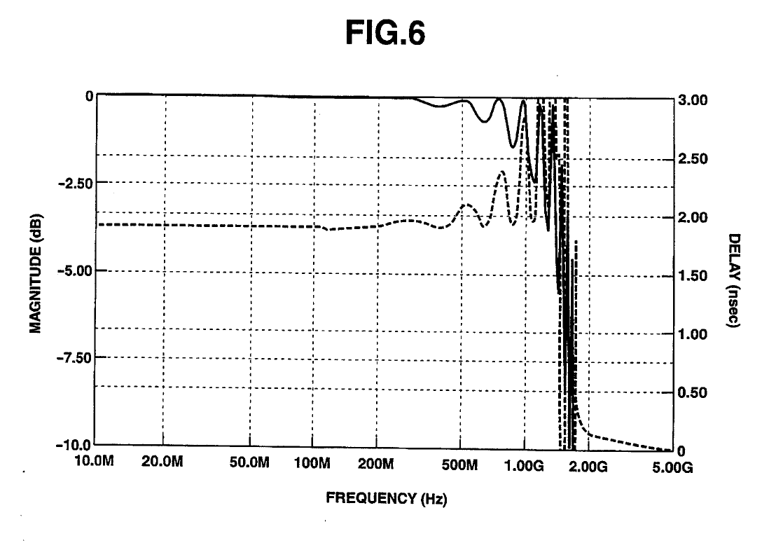

FIG. 6 shows the characteristics of the delay element 13 shown in FIG. 5. A solid line in the figure indicates the amplitude characteristic |eo/ei|. A dotted line 6 indicates delay characteristics (a delay time τ). The delay time (τ) is:

τ=ψ(ω)/ω

where:
ψ=amount of phase
ω=angular frequency.

The amplitude characteristic |eo/ei| represents a ratio of the amplitudes of the input voltage and the output voltage. As is clear from the delay characteristics shown in FIG. 6, the delay time (τ) is approximately 19 nsec, which coincides with the result of the equation (3). Also, the ripple of the delay time within the frequency range of up to 500 MHz can be as long as 0.175 nsec, and the ripple of the amplitude within the range of the 500-MHz range can be as large as 0.38 dB. In this manner, series connection of delay-line elements makes it possible to construct the delay element that obtains a desired amount of delay Da while the delay time characteristics and the amplitude characteristics with respect to the frequency are kept at a constant level. This implies that the delay elements 11 with the symbol Z⁻¹ shown in FIG. 2 can be constructed using the delay element 13. In this case, the delay elements 13 will be connected to other delay elements 13 in place of the resistor R1 and the resistor R2, and the series-connected delay elements 11 shown in FIG. 2 will be substituted by the series-connected delay elements 13.

The foregoing explanation assumed that the delay element 13 is a lossless circuit that only includes the inductance component and the capacitance component. Actually, however, the inductor L and the capacitor C that constitute the delay element are not a lossless element and accordingly the amplitude characteristics |eo/ei| becomes less than 1. In addition, it is necessary to connect the delay elements 13 shown in FIG. 5 to form multiple filter stages or sections and to obtain each tap from each of their corresponding connection points, which calls for impedance matching considerations in series connection of these circuits. The delay element which will be described in the following description of this embodiment offers a solution to these problems. How to effectuate the solution will be described later in detail.

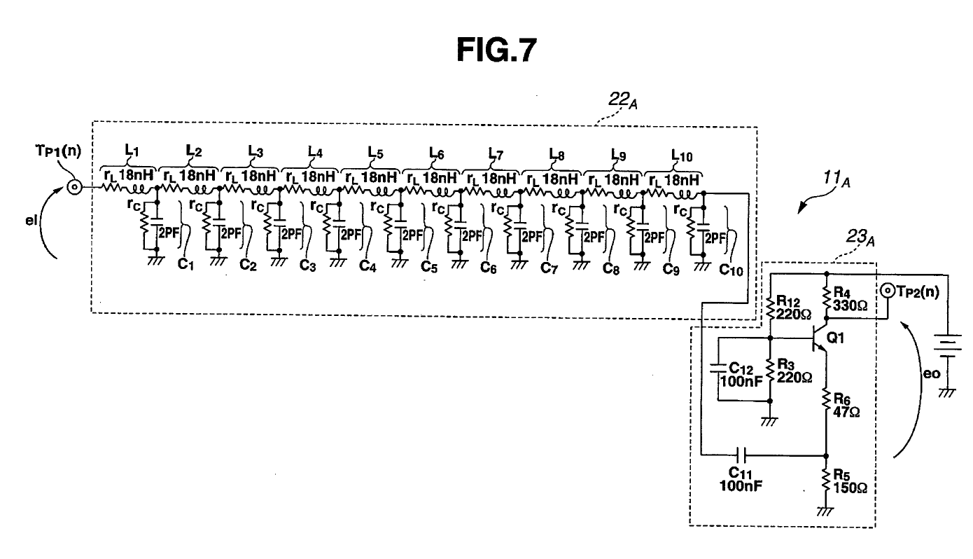

FIG. 7 illustrates a delay element 11A which is the delay element according to the preferred embodiment of the present invention. The delay element 11A corresponds to the delay element 11 illustrated in FIG. 2. The delay element 11A is constituted by a delay line 22A and an amplifier 23A. The delay line 22A is functionally equivalent to the delay element 13 shown in FIG. 5. The delay line 22A is composed of series-connected delay-line elements. The delay-line element is a low pass filter having an inductor and a capacitor that have parasitic resistance.

Since an actual inductor or an inductance coil involves not only inductance but also resistance and AC loss, the resistance and the AC loss can be represented by a resistor that is series-connected to the inductance. For example, the delay line 22A shown in FIG. 7 has the inductor L1 that is composed of an inductance coil of 18 nanohenrys (nH) and a resistor r_{L} connected in series to the inductance coil. In addition, since an actual capacitor involves not only capacitance but also dielectric loss, the capacitance and the dielectric loss are represented by a resistor that is connected in parallel to the capacitor. For example, the delay line 22A shown in FIG. 7 has the capacitor C1 that includes a capacitor of two picofarads (PF) and a resistor r_{C} that is connected in parallel to the capacitor. Also, resistance of the resistor r_{L} is smaller than that of the terminating resistor R1, and the resistance of the resistor r_{C} is larger than that of the terminating resistor R1. Although these components does not affect the characteristics of the despreading filter significantly, as has been discussed above, these components can cause the |eo/ei| to be less than one, making it difficult to obtain desired characteristics of the despreading filter.

In addition to the above-identified problem, the problem of impedance matching has also to be taken into consideration. Construction of the despreading filter 10 shown in FIG. 2 entails impedance matching because a multiplier circuit has to be connected to each of the delay elements respectively so that an output signal output by each of the delay elements is multiplied by a predetermined coefficient (i.e., a tap coefficient) of either +1 or −1. When impedance of the multiplier circuit having the tap coefficient is not infinite and not negligible compared with the characteristic impedance Z_{O}, it is not possible to meet the requirement that the delay-line elements have to be connected in series at an equal impedance, and as a result desired characteristics of the despreading filter fail to be obtained. This problem also occurs not only in a case where the delay-line elements are constructed by an inductor and a capacitor that are affected by parasitic resistance but also in a case where the delay-line elements are constructed by an ideal inductor and an ideal capacitor that are free from the parasitic resistance.

In order to address these problems existing in the art, the architecture of the delay element 11A shown in FIG. 7 is such that an output of the last delay-line element, i.e., a connection point between an inductor L₁₀ and a capacitor C10, which constitute the last stage of the delay line composed of the plurality of the series-connected delay-line elements, is connected to an input of the amplifier 23A, and an output T_{P2}(n) of the amplifier 23A, which also is an output of the delay element 11A, is connected to a subsequent circuit. The despreading filter, i.e., the correlator, is constructed by connecting in series a plurality of the delay elements 11A. The parenthesized “n” that appears in the input T_{P1}(n) the output T_{P2}(n) of the delay element 11A is an ordinal number n assigned to the specific delay element 11A according to its order in the sequence of all the delay elements 11A that constitute the despreading filter. A voltage at the input T_{P1}(1) of the delay element 11A is represented by “ei”. Likewise, a voltage at the output T_{P2}(n) of the delay element 11A is represented by “eo”.

Still referring to FIG. 7, in a similar manner as in the despreading filter 10 shown in FIG. 2, the plurality of the delay elements 11A are connected in series so that the despreading filter is configured. The input T_{P1}(1) is an input of the first delay element 11A, to which the signal x(t) is input. Also, the output T_{P2}(1), which also is an output of the first delay element 11A, is connected to an input T_{P1}(2) of the next-stage (i.e., second) delay element 11A. Further, an output T_{P2}(2) of the second delay element 11A is connected to an input TP₁(3) of the further next-stage (i.e., third) delay element 11A. In this manner, the delay elements are connected in series and an output T_{P2}(n−1) of the (n−1)th delay element 11A is connected to an input T_{P1}(n) of the n-th (i.e., the last) delay element 11A. An output T_{P2}(n) of the n-th delay element 11A is not connected to another subsequent delay element 11A. Also, the input T_{P1}(1) of the first delay element 11A is terminated with impedance equal to the characteristic impedance.

The basic principle of the impedance matching for the despreading filter constructed by the series-connected delay elements 11A can be summarized as follows. The output of the delay line 22A of the delay element 11A has to be terminated with the impedance equal to the characteristic impedance. Accordingly, the output of the delay line 22A is terminated at an input of the amplifier 23A, so that the impedance matching is obtained by setting the impedance at the input of the amplifier 23A equal to the characteristic impedance of the delay line 22A. Since the output of the delay line 22A is terminated with the characteristic impedance, the delay element 11A can serve as a transmission path with desired characteristics, and the input impedance of the delay element 11A can be made equal to the characteristic impedance.

Also, the outputs T_{P2}(1) to T_{P2}(n) of the first to the n-th delay elements 11A are respectively connected to their corresponding subsequent circuits so that the impedance matching is obtained with respect to their subsequent circuits. If the output T_{P2}(n) of the n-th delay element 11A is to be connected to an input T_{P1}(n+1) of an (n+1)th delay element 11A, then the subsequent circuits are (a) a multiplier circuit that multiplies (XORs) its input signal by the predetermined coefficient and (b) the next-stage (n+1)th delay element 11A having the input T_{P1}(n+1). When only connecting the multiplier circuit that multiplies a signal output on the output T_{P2}(n) of the n-th delay element 11A by the predetermined coefficient, the subsequent circuit for the n-th delay element 11A will only include the multiplier circuit.

It should be noted that the “impedance matching with respect to the subsequent circuit” means that (a) the impedance with which the input T_{P1}(n+1) of the (n+1)th delay element 11A is terminated is made equal to the characteristic impedance of the delay element 11A, the impedance being determined by the output impedance at T_{P2}(n) of the n-th delay line and the impedance of the multiplier circuit and (b) the impedance with which an input of the multiplier circuit is terminated is made at a predetermined value, the impedance being determined by the output impedance of the output T_{P2}(n) of the n-th delay line 11A and an input impedance at the input T_{P1}(n+1) of the (n+1)th delay line 11A (the characteristic impedance of the delay line 22A).

The following explains how the impedance of the input of the amplifier 23A is made equal to the characteristic impedance of the delay element 11A. The impedance of the input of the amplifier 23A is determined by the input impedances of the resistors R5, R6, and the transistor Q1. Accordingly, the resistor R5, the resistor R6 are to be adjusted so that the impedance at the input of the amplifier 23A becomes equal to the characteristic impedance Z_{O} (100Ω in this embodiment) of the delay line 22A expressed by the equation (1). Thus, the amplitude characteristics are made flat so that a delay time is obtained independently of the frequency. Also, the impedance at the output of the delay element 14A is mainly determined by the resistance of the resistor R4, and accordingly the resistor R4 is to be adjusted to set the impedance at the output of the delay element 11A. While the impedance at the output at this point is defined as described above, the subsequent circuit for the n-th delay element 11A only includes the multiplier circuit having the predetermined coefficient and accordingly a resistor having an impedance equal to the characteristic impedance Z_{O} (100Ω) of the delay line 22A is connected in parallel to the resistor R4.

Next, the following describes the compensation of a loss that occurs in the delay line. The compensation of the loss is to make the output voltage of the delay element 11A equal to the input voltage of the delay element 11A, Since |eo/ei| is the ratio of the output voltage and the input voltage of the delay element 11A, the value of |eo/ei| after the loss has been compensated for will be one (1).

Referring to FIG. 7 that focuses on the delay element 11A constituting one filter stage or section of the despreading filter 10, the degradation of the amplitude is compensated for by the amplifier 23, which is the grounded-base amplifier circuit that amplifies a signal amplitude and mitigates the degradation of the signal amplitude. A resistor R12 and a resistor R3 are used to establish base bias. A capacitor C12 is a decoupling capacitor and the capacitor C11 is a coupling capacitor. Also, as has been discussed, the resistors R5 and R6 are used to change the terminal impedance of the delay line 22A. The resistor R4 is used to change the output impedance of the amplifier 23A, which also is the output impedance of the delay element 11A. Further, it is possible to mitigate the degradation of the signal amplitude affected by the loss that was caused by the parasitic resistance Through selecting as required the impedance values of the resistors R4, R5, and R6, the |eo/ei| of the delay element 11A can be made at one (1) when the delay elements 11A are connected in series so as to serve as an inverse correlation filter.

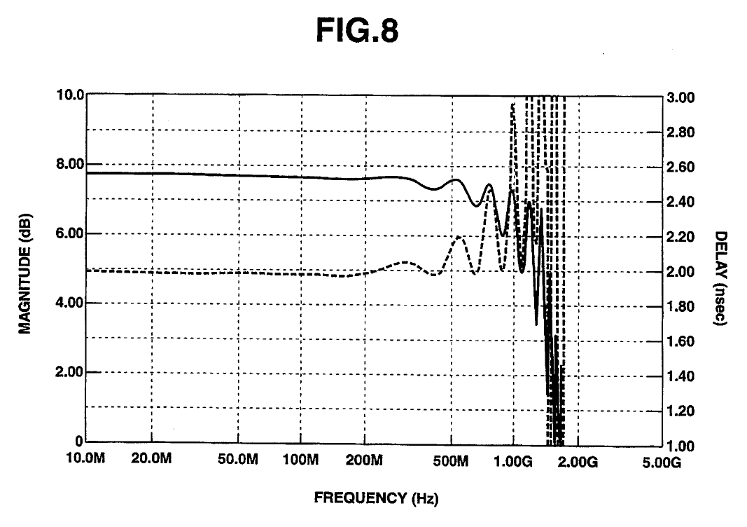

FIG. 8 shows the characteristics of one single delay element 11A shown in FIG. 7 when the delay elements 11A are not connected in series to serve as despreading filter stages. A solid line in FIG. 8 indicates the amplitude characteristics |eo/ei|. A dotted line in FIG. 8 indicates the delay characteristics. As shown in FIG. 8, the amplitude (magnitude) is as large as eight dB. When connecting in series the delay elements 11A shown in FIG. 7, the magnitude (amplitude) of the delay element to which the next circuits (i.e., the delay element 11A constituting the next filter stage and the multiplier circuit having the predetermined coefficient) are connected will be 0 dB due to an input impedance of the next-stage delay element 11A and the input impedance of the multiplier circuit.

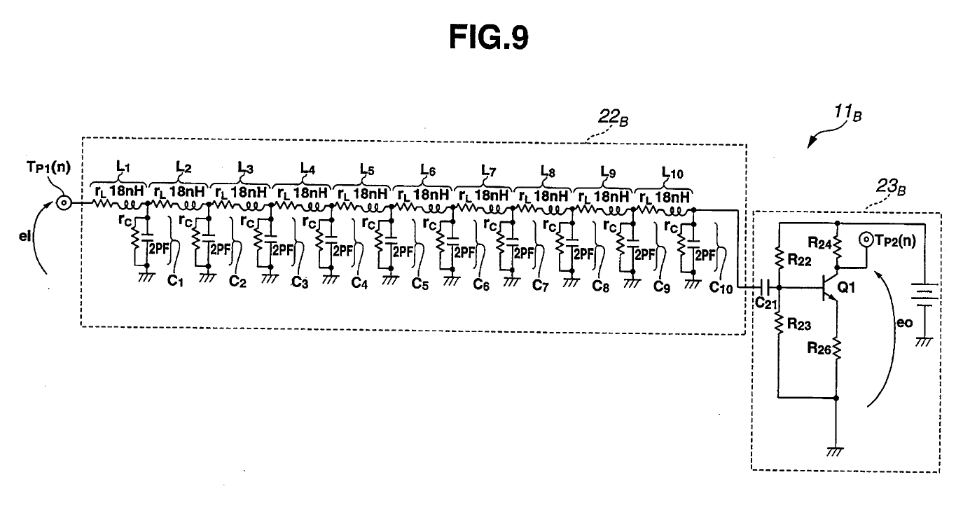

FIG. 9 is a circuit diagram of a delay element 11B serving as one despreading filter stage, which is constructed by a delay line 22B and an amplifier 23B. The amplifier 23B is a grounded-emitter amplifier circuit. The delay line 22B has the same configuration as that of the delay line 22A shown in FIG. 7. The delay element 11B corresponds to the delay element 11 shown in FIG. 2. In the grounded-emitter amplifier circuit 23B shown in FIG. 9, the bias voltage of the biasing circuit is specified through the setting of the resistance ratio between a resistor R22 and a resistor R23, and the impedance of the terminating resistor of the delay line 22B is mainly determined through a resistance value when assuming that the resistor R22 and the resistor R23 are connected in parallel. Accordingly, the impedance can be adjusted by selecting as required the resistance values of the resistors R22 and R23. Also, the resistor R24 defines the impedance for the subsequent circuit that is connected to the delay element 11B, and accordingly by selecting as required a resistance value of the resistor R24, impedance can be adjusted with respect to the subsequent circuit that is connected to an output T_{P2}. Also, a degree of amplification degree can be defined as approximation as a resistance of the resistor R24 divided by a resistance of the resistor R26. Thus, the degradation of amplitude at each filter stage can be corrected through adjusting the resistance of the resistor R24 and the resistance of the resistor R26, so that the value of |eo/ei| becomes 1 (0 dB) when delay elements 11B are connected in series. The capacitor C21 is a coupling capacitor.

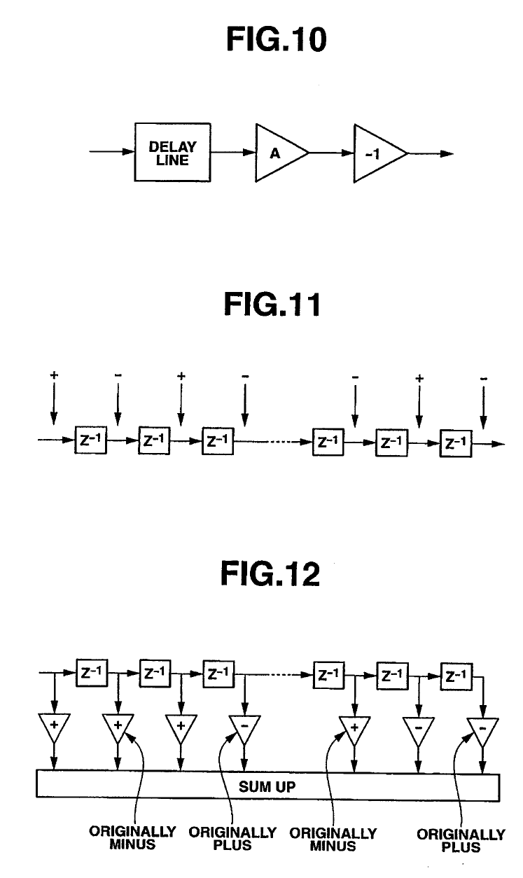

FIG. 10 shows an equivalent circuit for explanation of the functionality of the delay element 11B shown in FIG. 9. A rectangle indicated by “DELAY LINE” in FIG. 10 represents a portion that is constituted by the inductors L1 to L10 and the capacitors C1 to C10 in FIG. 9. A triangle indicated by a symbol “A” represents functionality of the grounded-emitter amplifier circuit with the degree of amplification degree A that compensates for attenuation in the delay line. Another triangle indicated by “−1” represents functionality of the inversion amplifier of the grounded-emitter amplifier circuit. The amplification degree A is specified taking into consideration the attenuation of the amplitude in the delay line, the attenuation of amplitude in a state where the subsequent circuit is connected. In this manner, the voltage magnitude of the input T_{P1} and the voltage magnitude of the output T_{P2} of one filter stage of the series-connected delay elements are made equal to each other, and thus even when multiple filter stages are constructed with the delay element 11B being one filter stage, the tap coefficient of the despreading filter has only to assume +1 and −1.

FIG. 11 shows the polarity of the output with respect to the input of each filter stage of the delay element 11B incorporating the grounded-emitter amplifier circuit. According to notation of FIG. 11, −1 represents a reverse phase where the polarity of the input is different from the polarity of the output. Likewise, +1 represents an in-phase where the polarity of the input and the polarity of the output are the same. As has been discussed above, through adjustment of the value of A as required, a gain from the input through to the output of the delay element 11B is set to 0 dB, the tap coefficient of the despreading filter can be configured by +1 and −1 only. However, since the grounded-emitter amplifier circuit is in use, the polarity of the odd-numbered stages are inverted at an interval of one stage. Rectangles indicated by the symbol “Z⁻¹” represent the delay element 11B.

FIG. 12 explains how the tap coefficients of the despreading filter can be specified. The sequence of the original tap coefficients that correspond to the PN code is +1, −1, +1, +1, . . . −1, −1, +1 from left to right in the figure.

The first tap coefficient +1 corresponds to K1 in FIG. 2. The second tap coefficient −1 corresponds to K2 in FIG. 2. The third tap coefficient +1 corresponds to K3 in FIG. 2. The fourth tap coefficient +1 corresponds to K4 in FIG. 2. In the same manner, the (n−2)th tap coefficient −1 corresponds to Kn−2 in FIG. 2, the (n−1)th tap coefficient −1 corresponds to Kn−1 in FIG. 2, and the n-th tap coefficient +1 corresponds to Kn in FIG. 2. When the grounded-emitter amplifier circuit is in use, these coefficients will be changed to a sequence of +1, +1, +1, −1, . . . +1, −1, −1.

More specifically, the plus and minus signs of the even-numbered tap coefficients by which the output signals of the first, third, fifth and other subsequent odd-numbered inverting amplifiers are reversed. The ordinal number of the last delay element is less by one than the ordinal number n of the last tap coefficient and the total number of the delay elements is n−1. The last and therefore (n−1)th delay element is an odd-numbered one.

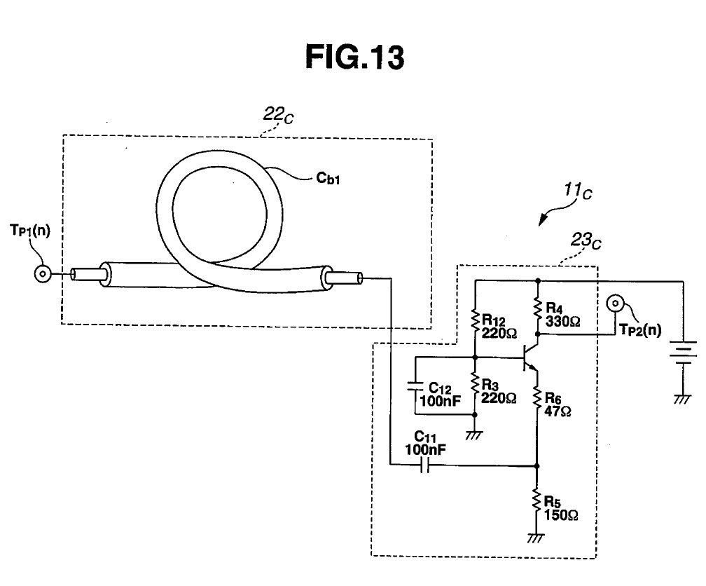

FIG. 13 shows a delay element 11C according to another embodiment of the present invention. The delay element 11C is configured by a delay line 22C and an amplifier 23C. The delay line 22C is a coaxial cable Cb1 in place of the inductors L1 to L10 and the capacitors C1 to C10 in the case of the delay line 22A. This circuit is a variant of the delay line circuit 22A shown in FIG. 7. When the coaxial cable Cb1 is in use, dimensions will be larger than those of the delay line 22A as a lumped-constant circuit shown in FIG. 7. Nevertheless, since the delay line 22C is equivalent to an infinite number of series-connected lumped-constant circuits, the amplitude characteristics and the delay characteristics with respect to the frequency are flat and favorable. In this case, the characteristic impedance can be made at a desired level by changing dimensions of the coaxial cable (a diameter of a core wire, a thickness of an insulating layer, a diameter of a core wire and a conducting wire surrounding the core wire), and, even when the plurality of the coaxial cables are connected in parallel, the characteristic impedance can be set at a desired level. The delay time can be specified in accordance with a length of the coaxial cable. In addition, the delay line circuit 22B constructed by the inductors L1 to L10 and the capacitors C1 to C10 shown in FIG. 9 can be replaced by the coaxial cable Cb1.

Also, as another embodiment, simple resistance addition can be available by manufacturing two types of delay elements, i.e., a polarity-inverting delay element and a polarity-non-inverting delay element and arranging them such that all of the tap coefficients are all set to +1, and thus the multiplier circuit with the tap coefficient and the adder circuit (SUM-UP) can be readily achieved. The delay element for one filter stage that reverses the polarity (i.e., polarity-inverting delay element) can be constructed using the grounded-emitter amplifier circuit and the delay element as one filter stage that does not reverse the polarity (i.e., polarity non-inverting delay element) can be readily obtained by serially connecting the polarity-inverting delay element to a subsequent grounded-emitter amplifier circuit. In other words, the polarity non-inverting delay element (when grounded-emitter amplifier circuit is in use) will be functionally equivalent to the equivalent circuit shown in FIG. 10 with one more triangle indicated by −1. Further, even a grounded-base amplifier that takes characteristics in consideration can be used to provide the delay element as one filter stage that does not reverses the polarity.

The following describes how the tap coefficients can be all set to +1. If the original values of the tap coefficients are given as +1, −1, +1, +1, . . . −1, −1, +1 from left to right, as the delay element indicated by the symbol Z⁻¹, in the order starting from the input to the output of the despreading filter, the first delay element is a polarity-inverting delay element, the second delay element is a polarity-inverting delay element, the third delay element is a polarity non-inverting delay element. If the polarity of the signal that is input to the previous stage (n−3)th delay element is in phase with respect to the polarity of the signal that is input to the first delay element, then the (n−3)th delay element is a polarity-inverting delay element, the (n−2)th delay element is a polarity non-inverting delay element, and the (n−1)th delay element is a polarity-inverting delay element. By connecting in series these polarity-inverting and non-inverting delay elements, the tap coefficients can be all set to +1. As previously explained, the number “n−1” is the ordinal number of the last delay element that is to be connected in series.

If the polarity of the signal that is input to the (n−3)th delay element has the reverse phase with respect to the polarity of the signal that is input to the first delay element, settings is different from the above-described settings where the polarity of the signal that is input to the (n−3)th delay element is in-phase with respect to the polarity of the signal that is input to the first delay element. Specifically, the (n−3)th delay element is a polarity non-inverting delay element, the (n−2)th delay element is a polarity non-inverting delay element, and the (n−1)th delay element is a polarity-inverting delay element appearance. In this manner, the tap coefficients can be all set to +1.

The same principles as described above can be relied upon for serially connecting the polarity-inverting delay element and the polarity non-inverting delay element so that the tap coefficients are all set to −1.

Although the above-described digital FIR filter whose tap coefficient assumes either +1 or −1 can be used as the despreading filter (matched filter) for ultrawideband radio receiving devices, it can also serve as a correlator for use in applications other than the direct-sequence-based UWB. Also, the preferred embodiment assumes that the chip rate is 500 Mcps in view of the currently effective government regulations under the Japanese Radio Law. Of course, the techniques described in the preferred embodiment is applicable to operation at a higher chip rate. Even in this case, use of a coaxial cable as the delay line does not prevent miniaturization of the despreading filter while fully exploiting the benefit of the coaxial cable. In any case, the despreading filter according to the preferred embodiment of the present invention can be positioned to address a higher chip rate that has hitherto not been realized by conventional techniques including the digital FIR filters and the SAW filters.

Also, even in operation at a lower chip rate, plurality of inductors and capacitors, which are lumped-constant components, can be used to construct the delay line in combination with the amplifier that compensates for the loss that occurs in the delay line. Thus, the despreading filter of the present invention can be adapted to low-chip-rate operation by increasing the inductance of the inductor and the capacitance of the capacitor while achieving cost-effectiveness of the despreading filter.

Having now fully described the device according to the preferred embodiment of the present invention, it is clear that the foregoing is illustrative of the present invention and is not to be construed as limiting the invention. Those skilled in this art will readily effectuate possible modifications and variations without materially departing from the spirit and scope of the present invention.

1. A correlator comprising:
(a) a plurality of delay elements that are connected in series and each output an output signal, the delay element including
a delay line configured by a plurality of delay-line elements that are connected in series, the delay-line element being a low pass filter that has an inductor and a capacitor and
an amplifier that compensates for a loss that occurs in the delay line so that an output voltage of the delay element is equal to an input voltage of the delay element;
the amplifier having
an input connected to an output of the delay-line element constituting a last stage of the delay line so such that impedance matching is obtained between the delay line and the amplifier and
an output connected to an input of a subsequent circuit such that the impedance matching is obtained between the amplifier and the subsequent circuit;
(b) a plurality of multipliers having a predetermined coefficient of either +1 or −1 and each configured to multiply corresponding each of the output signals supplied from the delay elements by the predetermined coefficient; and
(c) an adder that sums the output signals that have been multiplied by the predetermined coefficient.

2. The correlator as set forth in claim 1, wherein the amplifier of the delay element is a polarity-inverting amplifier that reverses a polarity of the output voltage with respect to a polarity of the input voltage, a sign of the predetermined coefficient is reversed for the output signal that has been output by an odd-numbered delay element of the series-connected delay elements, and the output signal output by the odd-numbered delay element is multiplied by the predetermined coefficient whose sign has been reversed.

3. An ultrawideband radio receiving apparatus that performs despreading of a received spectrum-spread signal by a correlator, the correlator comprising:
(a) a plurality of delay elements that are connected in series and each output an output signal, the delay element including
a delay line configured by a plurality of delay-line elements that are connected in series, the delay-line element being a low pass filter that has an inductor and a capacitor and
an amplifier that compensates for a loss that occurs in the delay line so that an output voltage of the delay element is equal to an input voltage of the delay element;
the amplifier having
an input connected to an output of the delay-line element constituting a last stage of the delay line such that impedance matching is obtained between the delay line and the amplifier and
an output connected to an input of a subsequent circuit such that the impedance matching is obtained between the amplifier and the subsequent circuit,
(b) a plurality of multipliers having a predetermined coefficient of either +1 or −1 and each configured to multiply corresponding each of the output signals supplied from the delay elements by the predetermined coefficient; and
(c) an adder that sums the output signals that have been multiplied by the predetermined coefficient.
